(19) United States
(12) Patent Application Publication
(10) Pub. No.: US 2020/0103944 A1
(43) Pub. Date: Apr. 2, 2020

(54) BOOK TO SMARTPHONE CASE ATTACHMENT

(71) Applicant: Laura Stephanie Boersma, Santa Monica, CA (US)

(72) Inventor: Laura Stephanie Boersma, Santa Monica, CA (US)

(21) Appl. No.: 16/146,070

(22) Filed: Sep. 28, 2018

(51) Int. Cl. G06F 1/16; H04M 1/215; H04M 1/02; H05K 5/02; H05K 5/00

(52) U.S. Cl. CPC G06F 1/1656; H04M 1/215; H05K 5/0086; H05K 5/0286; H04M 1/026

(57) ABSTRACT

A smartphone case attachment interface including a base having a front surface opposite a rear surface. Sidewalls extend upwardly from a periphery of the front surface. A slot is defined on the rear surface and includes an entrance and a button opening. The present invention further includes an attachment clip having a connector configured to attach to a book and a spring button. The attachment clip fits in the slot through the entrance against the bias of the spring button until the spring button snaps into the button opening, thereby releasably retaining the attachment clip to the base.

### BACKGROUND OF THE INVENTION

The present invention relates to a smartphone case and, more particularly, to a book to smartphone case attachment.

A smartphone is a handheld personal computer. It possesses extensive computing capabilities, including high-speed access to the Internet using both Wi-Fi and mobile broadband. Our smartphones are now such an ingrained part of our lives. When we have downtime waiting for a doctor appointment, car mechanic, on a flight, etc., our first place for entertainment is the smartphone.

As can be seen, there is a need for a smartphone case that allows a user to attach reading materials.

### SUMMARY OF THE INVENTION

In one aspect of the present invention, a smartphone case attachment interface comprises: a base comprising a front surface opposite a rear surface, sidewalls extending from a periphery of the front surface configured to retain a smartphone to the base, and a slot defined on the rear surface and comprising an entrance and a button opening; and an attachment clip comprising a connector configured to attach to a book and a spring button, wherein the attachment clip fits in the slot through the entrance against the bias of the spring button until the spring button snaps into the button opening, thereby releasably retaining the attachment clip to the base.

In another aspect of the present invention, a method of attaching a book to a smartphone case comprises steps of: providing a smartphone case comprising: a base comprising a front surface opposite a rear surface, sidewalls extending from a periphery of the front surface, and a slot defined on the rear surface and comprising an entrance and a button opening; attaching an attachment clip to a book, wherein the attachment clip comprises a spring button; and inserting the attachment clip into the slot through the entrance against the bias of the spring until the spring button snaps into the button opening.

These and other features, aspects and advantages of the present invention will become better understood with reference to the following drawings, description and claims.

### BRIEF DESCRIPTION OF THE DRAWINGS

FIG. 1 is a perspective view of an embodiment of the present invention;

FIG. 2 is a perspective view of an embodiment of the present invention;

FIG. 3 is an exploded view of an embodiment of the present invention;

FIG. 4 is a section view of the present invention taken along line 4-4 in

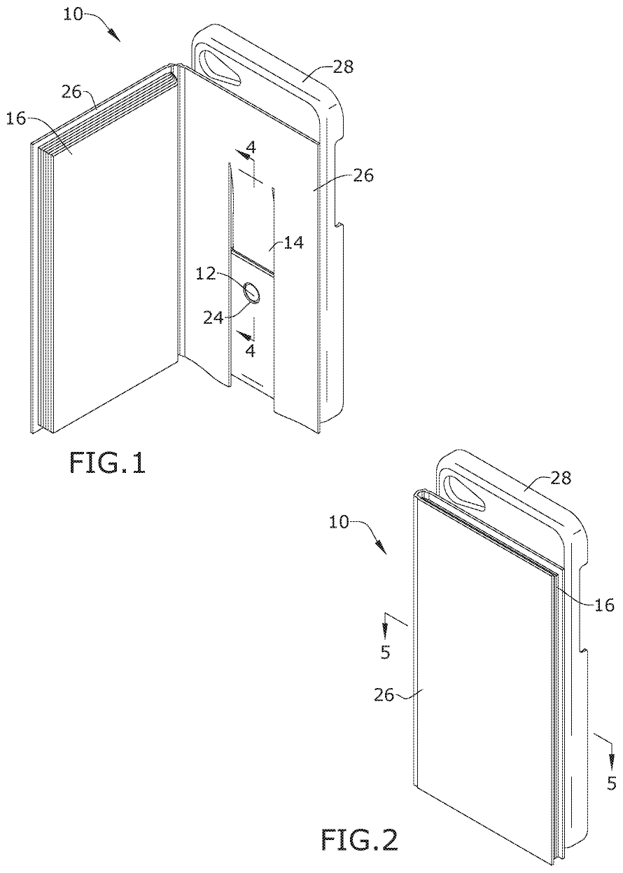

FIG. 1;

FIG. 5 is a section view of the present invention taken along line 5-5 in

FIG. 2;

FIG. 6 is a detailed section view of an embodiment of the present invention; and

FIG. 7 is a detailed section view of an embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

The present invention includes a smartphone case that attaches to a printed book. The present invention improves on traditional phone cases because it provides a way to keep your mind occupied but a break from the screen. The books attached to the case can easily be swapped out and traded. The books may be printed according to phone case size and attached with a connector on the back cover that slides into the phone case. To make the present invention, a case is measured against a pre-existing smartphone and sized to fit. The smartphone size also dictates the printed book size so the book fastens to the back of the case. When the book is finished, the case can be used again with another book of the same size with the connector.

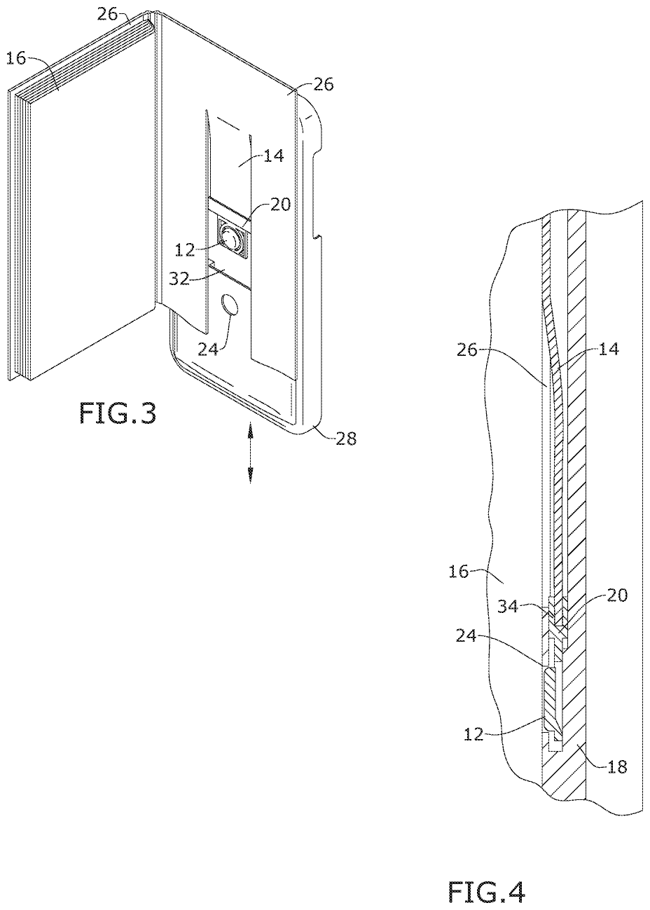

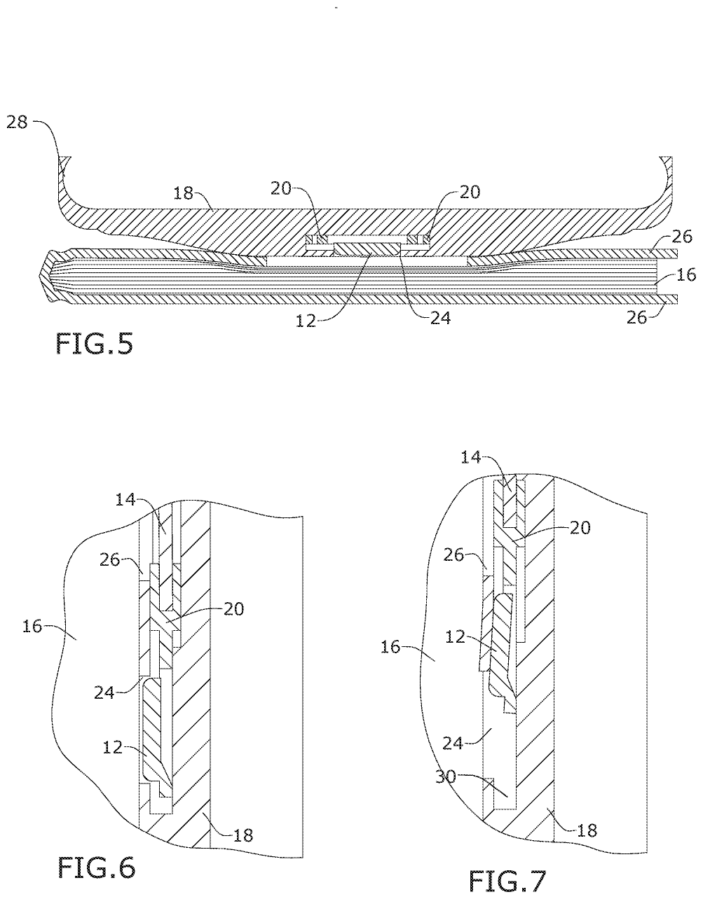

Referring to FIGS. 1 through 7, the present invention includes a smartphone case attachment interface 10. The smartphone case includes a base 18 having a front surface opposite a rear surface. Sidewalls 28 extend upwardly from a periphery of the front surface. The sidewalls 28 are curved inwards and shaped to retain a smartphone to the base 18. A slot 30 is defined on the rear surface and includes an entrance 32 and a button opening 24. The present invention further includes an attachment clip 20 having a connector 34 configured to attach to a book 16 and a spring button 12. The attachment clip 20 fits in the slot 30 through the entrance 32 against the bias of the spring button 12 until the spring button 12 snaps into the button opening 24, thereby releasably retaining the attachment clip 20 to the base 18.

In certain embodiments, the book 16 includes a book cover 26 having a cutout portion and a flap 14 extending into the cutout portion. The flap 14 includes a bottom edge. In such embodiments, the connector 34 is a channel configured to attach to an edge of a book cover 26 of the book 16. When the attachment clip 20 is secured to a bottom edge of the flap 14 of the book cover 26, the user may insert the attachment clip 20 into the slot 30 until the spring button 12 snaps into the button opening 24 and the book 16 is then attached to the rear the phone case.

A method of attaching a book to a smartphone case includes: providing the smartphone case described above; attaching an attachment clip to a book, wherein the attachment clip comprises a spring button; and inserting the attachment clip into the slot through the entrance against the bias of the spring until the spring button snaps into the button openings. The method may further include the step of inserting the bottom edge of the flap into the channel, thereby connecting the attachment clip to the book cover.

It should be understood, of course, that the foregoing relates to exemplary embodiments of the invention and that modifications may be made without departing from the spirit and scope of the invention as set forth in the following claims.

What is claimed is:

1. A smartphone case attachment interface comprising:
a base comprising a front surface opposite a rear surface, sidewalls extending from a periphery of the front surface configured to retain a smartphone to the base, and a slot defined on the rear surface and comprising an entrance and a button opening; and
an attachment clip comprising a connector configured to attach to a book and a spring button, wherein
the attachment clip fits in the slot through the entrance against the bias of the spring button until the spring button snaps into the button opening, thereby releasably retaining the attachment clip to the base.

2. The smartphone case attachment interface 1, wherein the connector is a channel configured to attach to an edge of a book cover of the book.

3. A method of attaching a book to a smartphone case comprising:
providing a smartphone case comprising:
a base comprising a front surface opposite a rear surface, sidewalls extending from a periphery of the front surface, and a slot defined on the rear surface and comprising an entrance and a button opening;
attaching an attachment clip to a book, wherein the attachment clip comprises a spring button; and
inserting the attachment clip into the slot through the entrance against the bias of the spring until the spring button snaps into the button opening.

4. The method of claim 3, wherein the book comprises a book cover having a cutout portion and a flap extending into the cutout portion, wherein the flap comprises a bottom edge.

5. The method of claim 4, wherein the connector of the attachment clip is a channel.

6. The method of claim 5, further comprising the step of:
inserting the bottom edge of the flap into the channel, thereby connecting the attachment clip to the book cover.
